(19) United States
(12) Patent Application Publication
(10) Pub. No.: US 2013/0293402 A1
(43) Pub. Date: Nov. 7, 2013

(54) TEST OF AN EMBEDDED ANALOG-TO-DIGITAL CONVERTER

(71) Applicant: STMICROELECTRONICS (GRENOBLE 2) SAS, Grenoble (FR)

(72) Inventor: Herve NAUDET, Meylan (FR)

(73) Assignee: STMICROELECTRONICS (GRENOBLE 2) SAS, Grenoble (FR)

(21) Appl. No.: 13/874,658

(22) Filed: May 1, 2013

(30) Foreign Application Priority Data
May 7, 2012 (FR) 1254167

(51) Int. Cl. H03M 1/10

(52) U.S. Cl. CPC H03M 1/1071
USPC 341/120

(57) ABSTRACT

A method for testing an analog-to-digital converter (ADC) includes applying ramps to the input of the converter, and classifying the digital codes produced by the converter according to a histogram. The converter is declared operational as soon as all the classes of the histogram have reached a minimum count. The minimum count may be equal to 1 in practice. The converter is declared defective if any class does not reach the minimum count before expiry of a time interval.

### FIELD OF THE INVENTION

The invention relates to a method for testing integrated circuits during production, and, more particularly, for testing an analog-to-digital converter embedded in a system-on-chip.

### BACKGROUND OF THE INVENTION

FIG. 1 shows a classic methodology used to test an analog-to-digital converter (ADC). A linear ramp, relatively slow compared to the sampling frequency of the converter, is applied at the analog input Va of the converter, such that several successive samples can be taken for each digital code Vd of the converter. The occurrences N of each code are counted and classified in a histogram H.

Ideally, when the ramp has scanned the input dynamic range of the ADC converter, the classes of the histogram all contain the same count. Differences between the counts reflect defects in the linearity of the converter (or of the ramp). The converter may be declared defective if a too significant difference is found.

In practice, the sampling of the ramp is affected by noise, and the ramp is not perfectly linear. The result is that a measurement is taken on a large number of samples to mitigate the noise by an averaging effect. The non-linearities of the ramps visible on the full scale of the ADC converter are offset by taking the measurement on a large number of small successive ramps.

In a test during the production of integrated circuits, generic test equipment is generally used that is capable of producing various test signals and of collecting the data, for example, using a JTAG interface. To test an analog-to-digital converter, the test equipment produces the ramps and collects the codes produced by the converter to store them. These codes are then transferred onto a workstation capable of analyzing them more rapidly than the test equipment.

The time required to transfer the data from the test equipment to the workstation may represent a significant portion of the total time for testing the ADC converter. While the transfer time remains acceptable for converters up to 10 bits, it may becomes too long for converters of 12 bits and more. The number of samples to be taken to obtain acceptable statistical measurement accuracy increases exponentially with the number of bits of the converter. For example, for a 12-bit converter, it is recommended to work on a series of at least 512 k samples. The transfer of such a number of samples represents almost 90% of the testing time.

To reduce the testing time linked to the transfer of the samples, the use of built-in self-test devices (BIST) has been proposed, which enables the ramps to be generated internally and the samples to be processed on-the-fly.

U.S. patent application 2011/0231153 describes such a device. It enables programming of the nominal number of samples to be taken per code, and thus the slope and the number of ramps according to the sampling frequency. Once the corresponding number of samples are taken and classified in a histogram, the device establishes the difference between the maximum count and the minimum count of the classes of the histogram. The user can program a threshold for this difference, above which the converter will be considered defective.

The test duration of such a BIST device is proportional to the number of samples to be taken per code. The user thus needs to choose a compromise between accuracy and test duration.

The ramps are generated by analog components configured to achieve a maximum linearity. It appears that the analog portion occupies the major part of the surface area of the BIST device. Such a device is thus relatively large and is therefore used only for the largest systems-on-chip so that the influence on the manufacturing cost is minimum.

Furthermore, the behavior of the analog components depends on the manufacturing technology of the system-on-chip. The slightest change to the technology requires a readjustment of the analog part of the BIST device. The device is not portable as such from one technology to another and may require a full, rather long re-qualification cycle.

### SUMMARY OF THE INVENTION

There is thus a need for a BIST device for testing analog-to-digital converters that is capable of assessing the proper operation of the converter within a desired or minimum period of time.

It may also be desirable for the BIST device to occupy little surface area and be portable from one technology to another.

These and other objects, features and advantages may be addressed by providing a method for testing an analog-to-digital converter comprising applying ramps to the input of the converter and classifying the digital codes produced by the converter according to a histogram. The converter is declared operational as soon as all the classes of the histogram have reached a minimum count. The minimum count may be equal to 1 in practice. The converter may be declared defective if a class does not reach the minimum count before expiry of a time-out.

According to an embodiment, the ramps are produced from a filtered pulse width modulation signal.

A device may be provided for testing an analog-to-digital converter, comprising a ramp generator connected to the input of the converter, and a test unit configured to classify the digital codes produced by the converter according to a histogram in a memory. The test unit is configured to activate a pass signal as soon as all the classes of the histogram have reached a minimum count.

According to an embodiment, the ramp generator comprises a pulse width modulator followed by a filter.

According to an embodiment, the device comprises an address decoder receiving the output of the converter as an address; a flip-flop per output of the address decoder, connected to store the transition of the output of the decoder through an active state; and the test unit configured to activate a pass signal when all the flip-flops have toggled.

According to an embodiment, the device comprises a timer started at the beginning of a test phase; and the test unit is configured to activate a fail signal if all the flip-flops have not toggled when the timer reaches its time-out.

According to an embodiment, the analog-to-digital converter, the pulse width modulator, the test unit, and the memory are all integrated into a same system-on-chip.

According to an embodiment, the analog-to-digital converter, the pulse width modulator, the test unit, and the flip-flops are all integrated into a same system-on-chip, and the flip-flops have a test operating mode in which they are connected to the outputs of the address decoder, and a normal operating mode in which they are used by other functions of the system-on-chip.

### BRIEF DESCRIPTION OF THE DRAWINGS

Some embodiments will be explained in the following description, in relation with, but not limited to, the following figures, in which:

FIG. 1, described above, shows a classic methodology for testing an analog-to-digital converter as in the prior art;

FIG. 2 schematically represents one embodiment of a self-adapting BIST device in accordance with the invention; and

FIG. 3 schematically represents a system-on-chip integrating a BIST device and a digital ramp generator in accordance with the invention.

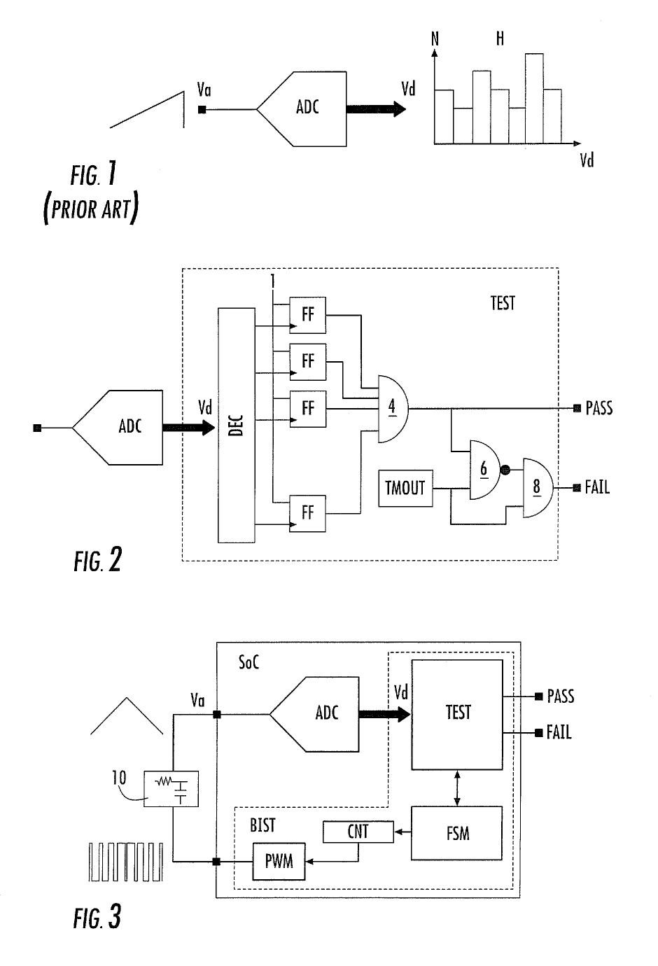

### DETAILED DESCRIPTION OF THE PREFERRED EMBODIMENTS

A BIST device of the type described in U.S. patent application 2011/0231153 enables particularly accurate measurements to be taken and small linearity differences of the analog-to-digital converter to be detected. This is useful to detect the causes of failures and to perform prototype characterization.

In a mass production environment, a go/no go criterion is sought that need not be programmed on a case-by-case basis.

In practice, when a robust design methodology is used for the circuits, i.e. enabling the circuits to be operational in a worst-case situation of variability of the manufacturing process, of the supply voltage, and of the temperature, a failure generally results in such a significant linearity defect that there is no need to measure it accurately.

Generally speaking, instead of trying to measure differences between histogram classes, the aim here is merely to detect that each digital code is produced by the converter in response to a ramp that scans the entire input dynamic range of the converter. In other words, the aim is to reach a minimum value in each class of the histogram, and this minimum value may be 1 in practice.

Applicants theorize without wishing to be bound thereto that it would be sufficient to use a single ramp configured so that a single sample is taken for each code. However, given the influence of the noise, it is likely that not all the codes are produced in a single attempt. However, the fact that a code is effectively produced is representative of the proper operation of the converter for this code: either the ramp corresponded to the value of the code, or the noise shifted the value of the ramp to match it to the code. In the framework of robust circuit design, if a code is produced, there is no doubt that the linearity is acceptable. A failure will rather cause an absence of a code, whatever the value of the signal applied at the input of the converter.

Given these observations, it can be deduced that the linearity of the ramp may have little or no importance. What matters is to scan all the values of the input dynamic range of the converter slowly enough and to observe that all the codes are produced. If not all the codes are produced, this may be due to the noise: scanning operations are repeated until production of all the codes is observed. If there are missing codes after a number of scanning operations statistically sufficient to smooth the noise, the converter is declared defective.

FIG. 2 schematically represents one embodiment of a BIST device, in particular a test unit configured to analyze the samples, enabling a particularly simple implementation of this procedure. The output of the analog-to-digital converter ADC is supplied to an address decoder DEC. For each digital code Vd of the converter, the address decoder activates a different output line. Each of these output lines is connected to the enable input of a respective flip-flop FF. The data inputs of all of these flip-flops receive the value “1”. An AND gate 4 combines the outputs of the flip-flops FF and produces a PASS signal that is active when all flip-flops FF have toggled to “1”.

A NAND gate 6 combines the PASS signal and the output of a timer TMOUT. An AND gate 8 combines the outputs of gate 6 and of timer TMOUT. It produces a FAIL signal that is active when timer TMOUT has finished counting its time and if the PASS signal has not been activated.

At the beginning of a test phase, the flip-flops FF are set to “0”. The timer TMOUT is started and a succession of ramps starts at the input of the converter. As the codes are produced, the flip-flops FF are toggled to “1”. As soon as all the flip-flops FF are at “1”, which may occur from the end of the first ramp, the PASS signal is activated and the test stops.

If the timer TMOUT reaches its time whereas the PASS signal has not been activated, the FAIL signal is activated, indicating the failure of the ADC converter.

With this test procedure, an operational converter can be detected from the first ramp. It is only if the converter is defective that the testing time is longer, equal to the time of the timer. Generally, in production, as the majority of circuits are operational, the average testing time is significantly reduced compared to an approach where the number of samples to be taken is constant and determined by the worst case conditions, which would correspond to the time of the timer TMOUT.

With the test procedure that has just been described, it is also possible to declare the converter operational if each code has been produced twice or more, instead of only once. In this case, the flip-flops FF in FIG. 2 are replaced with shift registers, the size of which corresponds to the desired minimum value of the number of code occurrences. The test procedure remains the same.

As previously indicated, the ramps applied to the analog input of the ADC converter do not require an accurate linearity. Therefore, it is proposed to generate a ramp internally using digital devices that can be found in most systems-on-chip. The ramp generator then becomes portable from one technology to another without any adaptation. In addition, its surface area will be significantly smaller than that of an analog generator.

FIG. 3 schematically shows a system-on-chip integrating a BIST device and one embodiment of a digital ramp generator. The ramp generator comprises a digital pulse width modulator PWM. The pulse width is programmed by a counter CNT. The output signal of the PWM modulator is supplied to a low-pass filter 10 that produces the desired ramp. The different elements of the BIST device are managed by a finite state machine FSM, which may implement the various test phases described here.

The filter 10 has no strict requirements: it can be as simple as an R-C filter. However, as the frequency of the ramp can be relatively low, the capacitor of the filter may have a value incompatible with integration into the system-on-chip. Therefore, as shown, it is provided outside the circuit, mounted on the test support of the integrated circuit. This passive filter may not require any adjustment or power supply: its presence is thus transparent during the test.

The resolution of the PWM modulator does not need to be equal to that of the analog-to-digital converter. It is the filter 10 that produces a continuous variation between two consecutive discrete values of the PWM modulator. For a 12-bit converter resolution, a 9-bit resolution may be sufficient for the PWM modulator and the counter CNT, for example.

The PWM modulator then operates on 512 clock cycles. If N is the content of counter CNT, the PWM modulator sets its output to “1” during N clock cycles, and to “0” during 512-N cycles. The 9-bit dynamic range of the modulator is thus scanned in 512 phases of 512 cycles. A ramp thus lasts 512×512=262,144 clock cycles. Assuming that the frequency of the PWM modulator is equal to the sampling frequency, the slope of the ramp is such that on average 262,144/4,096=64 samples are taken per 12-bit code. The number of samples per code can be reduced by decreasing the resolution of the PWM modulator or by decreasing the sampling frequency compared to the frequency of the PWM modulator.

Preferably, as shown in FIG. 3, a triangle wave is generated rather than a succession of ramps. This is done using the counter CNT alternately in up-counting mode and in down-counting mode. A triangle wave is particularly well adapted to ADC converters using switched capacitors. Indeed, the alternation of positive variations and negative variations has a compensatory effect in such structures.

In practice, the dynamic range of the ramp is that of the supply voltage of the PWM modulator, for example 3.3V. The input dynamic range of the ADC converter is often lower, for example 1V. In this case, the dynamic range of the ramp is preferably adapted to that of the ADC converter. To that end, it is possible to proceed in the following manner. During an initial phase of the test, state machine FSM causes the generation of a “full scale” ramp, starting counter CNT at 0 and making it count up to its maximum value. The state machine FSM stores the two counts for which the minimum code (000 . . . ) and the maximum code (111 . . . ) produced by the ADC converter are respectively observed.

During the test, counter CNT is then only used between the two counts thus found. The duration of the ramps is decreased proportionally: with the numeric example above, the ramps only last for 30% of the duration of the full-scale ramps, and 0.3×64=19.2 samples are taken per code of the ADC converter.

To save time during tests, the counts defining the dynamic range can be established during the qualification phase of the product (pre-production analysis), and then programmed in a non-volatile memory of the circuits in production, usable immediately by the state machine FSM.

All the elements of the BIST device are digital and simple: they occupy a significantly smaller surface area than a BIST structure incorporating an accurate analog ramp generator. The element occupying the largest surface area could be the set of flip-flops FF, of which there are 4,096 for a 12-bit converter. However, these flip-flops can be reused flip-flops of the system-on-chip. The system-on-chip is likely to incorporate many flip-flops. In a test phase of the digital circuits of the system, the flip-flops are configured in a scan-chain, i.e. as a shift register enabling test vectors to be introduced and the results to be extracted. This configuration of the flip-flops is selected by multiplexers. It is sufficient to modify some of these multiplexers to allow for a third configuration, that of the flip-flops FF in FIG. 2, selected in the test phase of the ADC converter.

It is possible to consider other means or approaches of generating a ramp of simple structure. For example, the complementary transistors normally provided to drive an output pad can be configured to operate as constant current generators, and be controlled by a square-wave signal. The filter 10 is then replaced with an integration capacitor. When the control signal is high, the capacitor charges at a constant current, thus according to an increasing linear ramp. When the control signal is low, the capacitor discharges at a constant current.

In this case, analog properties of the output transistors are nonetheless used that are not necessarily portable from one technology to another. To overcome this, an integrator may be provided outside the circuit, instead of the filter 10, receiving a square-wave voltage signal from the BIST device. Being an active device, the integrator requires a power supply source. In addition, means or circuitry would be required for setting the dynamic range of the ramps according to the reduced input dynamic range of the ADC converter, for example, by setting the frequency of the square-wave signal. This amounts to a built-in system for adjusting the properties of a rectangular signal, similar to a PWM modulator.

1-10. (canceled)

11. A method for testing an analog-to-digital converter (ADC) comprising:
applying a plurality of ramps to an input of the ADC;
classifying digital codes produced by the ADC in response to the plurality of ramps, according to a histogram having a plurality of classes; and
declaring the ADC operational as soon as all of the plurality of classes of the histogram have reached a minimum count.

12. The method according to claim 11, wherein the minimum count is 1.

13. The method according to claim 11, further comprising declaring the ADC defective if any class does not reach the minimum count before expiry of a time-out interval.

14. The method according to claim 11, wherein the plurality of ramps are produced from a filtered pulse width modulation signal.

15. The method according to claim 11, wherein the classifying and declaring are performed by a test unit included as part of a system-on-chip device with the ADC.

16. The method according to claim 11, wherein the plurality of ramps comprises a plurality of triangular ramps.

17. A method for testing an analog-to-digital converter (ADC) comprising:
applying at least one ramp to an input of the ADC;
classifying digital codes produced by the ADC based upon the at least one ramp, according to a histogram having a plurality of classes; and
declaring the ADC operational based upon the plurality of classes of the histogram reaching a threshold.

18. The method according to claim 17, wherein the threshold comprises a minimum count.

19. The method according to claim 18, wherein the minimum count is 1.

20. The method according to claim 17, further comprising declaring the ADC defective if any class does not reach the threshold before expiry of a time-out interval.

21. The method according to claim 17, wherein the at least one ramp comprises a plurality thereof produced from a filtered pulse width modulation signal.

22. The method according to claim 17, wherein the classifying and declaring are performed by a test unit included as part of a system-on-chip device with the ADC.

23. The method according to claim 17, wherein the plurality of ramps comprises a plurality of triangular ramps.

24. A device for testing an analog-to-digital converter (ADC) comprising:
a ramp generator configured to generate a plurality of ramps input to the ADC; and
a test unit configured to
classify digital codes produced by the ADC in response to the plurality of ramps, according to a histogram having a plurality of classes and store the histogram, and
activate a pass signal as soon as all of the plurality of classes of the histogram have reached a minimum count.

25. The device according to claim 24, wherein said ramp generator comprises a pulse width modulator and a filter coupled thereto.

26. The device according to claim 24, wherein said test unit comprises a memory configured to store the histogram.

27. The device according to claim 25, wherein the ADC, said pulse width modulator, and said test unit are all integrated into a same system-on-chip.

28. The device according to claim 24, wherein said test unit comprises:
an address decoder configured to receive an output of the ADC as an address, and having a plurality of outputs; and
a respective flip-flop coupled to each of the plurality of outputs of said address decoder and coupled to store a transition of said address decoder through an active state.

29. The device according to claim 28, wherein said test unit is configured to activate a pass signal when all of said plurality of flip-flops have toggled.

30. The device according to claim 28, wherein the ADC and said test unit are all integrated into a same system-on-chip.

31. The device according to claim 28, wherein said plurality of flip-flops has a test operating mode in which it is coupled to the plurality of outputs of said address decoder, and a normal operating mode in which it is used by other functions of the system-on-chip.

32. The device according to claim 28, wherein said test unit comprises a timer started at the beginning of a test phase; and wherein said test unit is configured to activate a fail signal if all of said plurality of flip-flops have not toggled when said timer reaches its time.

33. An electronic device comprising:
an analog-to-digital converter (ADC);
a ramp generator configured to generate at least one ramp input to said ADC; and
a test unit configured to
classify digital codes produced by the ADC based upon the at least one ramp, according to a histogram having a plurality of classes, and
activate a pass signal based upon the plurality of classes of the histogram having reached a threshold.

34. The electronic device according to claim 33, wherein the threshold comprises a minimum count.

35. The electronic device according to claim 33, wherein said ramp generator comprises a pulse width modulator and a filter coupled thereto.

36. The electronic device according to claim 35, wherein said ADC, said pulse width modulator, and said test unit are all integrated into a same system-on-chip.

37. The electronic device according to claim 33, wherein said test unit comprises:
an address decoder configured to receive an output of said ADC as an address, and having a plurality of outputs; and
a respective flip-flop coupled to each of the plurality of outputs of said address decoder and coupled to store a transition of said address decoder through an active state.

38. The electronic device according to claim 37, wherein said ADC and said test unit are all integrated into a same system-on-chip.

39. The electronic device according to claim 37, wherein said plurality of flip-flops have a test operating mode in which it is coupled to the plurality of outputs of said address decoder, and a normal operating mode in which it is used by other functions of the system-on-chip.

40. The electronic device according to claim 37, wherein said test unit comprises a timer started at the beginning of a test phase; and wherein said test unit is configured to activate a fail signal if all of said plurality of flip-flops have not toggled when said timer reaches its time.

41. An integrated circuit comprising:
an analog-to-digital converter; and
a built-in self-test unit configured to
apply a ramp to an input of said analog-to-digital converter,
watch codes produced by said analog-to-digital converter, and
activate a pass signal when all the codes of said analog-to-digital converter have been produced;
said built-in self-test unit comprising a pulse-width modulator configured to produce the ramp.

42. The integrated circuit of claim 41, wherein said pulse-width modulator has a lower resolution than said analog-to-digital converter.

43. The integrated circuit of claim 41, wherein an output of said pulse-width modulator is configured to be coupled, during a test phase, to the input of said analog-to-digital converter through a low-pass filter.

44. The integrated circuit of claim 41, wherein said built-in self-test unit comprises:
an address decoder configured to receive an output of said analog-to-digital converter as an address;
a respective flip-flop coupled to each output of said address decoder and configured to store a transition of the respective output of said decoder through an active state; and
circuitry configured to activate the pass signal when all the flip-flops have toggled.

45. The integrated circuit of claim 44, wherein said built-in self-test unit comprises:
a timer configured to be started at a beginning of a test phase; and
circuitry configured to activate a fail signal if all the flip-flops have not toggled when said timer reaches a time-out.

46. The integrated circuit of claim 45, wherein the time-out is selected so that a number of produced ramps smoothes out noise.

47. The integrated circuit of claim 44, wherein said flip-flops are configured to have a test operating mode where said flip-flops are connected to the outputs of said address decoder, and a normal operating mode where said flip-flops are used by other functions of the integrated circuit.
